(19) United States
(12) Patent Application Publication
(10) Pub. No.: US 2013/0078804 A1
(43) Pub. Date: Mar. 28, 2013

(54) METHOD FOR FABRICATING INTEGRATED DEVICES WITH REDUCTED PLASMA DAMAGE

(71) Applicants: Jeng-Hsing JANG, Taoyuan County (TW); Yi-Nan CHEN, Taoyuan County (TW); Hsien-Wen LIU, Taoyuan County (TW)

(72) Inventors: Jeng-Hsing JANG, Taoyuan County (TW); Yi-Nan CHEN, Taoyuan County (TW); Hsien-Wen LIU, Taoyuan County (TW)

(73) Assignee: NANYA TECHNOLOGY CORPORATION, Taoyuan (TW)

(21) Appl. No.: 13/240,945

(22) Filed: Sep. 22, 2011

(51) Int. Cl. H01L 21/28; H01L 21/311

(52) U.S. Cl. 438/669; 438/694; 257/E21.158; 257/E21.257

(57) ABSTRACT

A method for fabricating an integrated device with reduced plasma damage is disclosed, including providing a substrate, forming a structural layer on the substrate, forming a photoresist layer on the structural layer, and performing an etching process to the structural layer, wherein the photoresist layer is conductive to reduce plasma damage during the etching process.

### BACKGROUND OF THE INVENTION

1. Field of the Invention

This invention generally relates to a process for the fabrication of integrated devices and more particularly to a process for the fabrication of integrated devices with reduction of damage from plasma.

2. Description of the Related Art

For the fabrication of the integrated devices which are on the market at present, the monocrystalline silicon wafers are subjected to a plurality of physical and chemical treatments which make it possible to define the topographies of the integrated electronic circuits.

In particular, for definition of electronic components in submicrometric technologies, extensive use is made of a process technique which is known as plasma etching, which makes it possible to etch thin films, which can be made of conductive materials and dielectric materials.

A known example of the application of the plasma etching technique is illustrated in FIGS. 1A-1C, in which a portion of a wafer 100 comprises a substrate 102 of semiconductor material and a structural layer 104 on top of the substrate 102. The structural layer 104 can for example be a layer of dielectric material, a layer of polycrystalline silicon, or a layer of metallization, which is intended to be defined by means of plasma etching.

As illustrated in FIG. 1B, on top of the structural layer 104, a mask layer 106 is produced in order to protect the portions which are not to be removed. In particular, the mask layer 106 is produced from a known material such as photoresist or resist material.

As illustrated in FIG. 1C, after the plasma etching has been carried out, a defined layer 108 is obtained. Referring to FIG. 2, during the plasma etching, an equal quantity of positive ions and electrons is directed towards the wafer 100, but in individual areas of the wafer 100 there are two mechanisms which lead to plasma damage to the wafer 100 i.e. lack of uniformity of the plasma 202 and a high electrical field, as a result of which more negative than positive charges reach certain areas on the wafer 100, whereas in other areas the contrary applies. The high electrical field from the plasma 202 in the chamber 204 leads the positive charges 206 on the structural layer 104 of sensitive material to be etched recall electrons from the substrate 102 (supported by a holder 208) beneath, thus giving rise to a passage of current and electrical field in the structural layer 104 of the devices. The electric currents which pass through the thin oxides of electronic devices can cause damage, modifying their properties and giving rise to problems of functioning of the devices themselves, or reducing their reliability over a period of time. Specifically, the semiconductor dimension is getting smaller and the gate oxide is thinner, so that the plasma 202 damage is getting worse.

### BRIEF SUMMARY OF INVENTION

The invention provides a method for fabricating an integrated device with reduced plasma damage, comprising providing a substrate, forming a structural layer on the substrate, forming a conductive photoresist layer on the structural layer, wherein the conductive photoresist layer is formed by doping a photoresist material with a conductive polymer, and performing an etching process to the structural layer.

The invention provides a method for fabricating an integrated device with reduced plasma damage, comprising providing a substrate, forming a structural layer on the substrate, forming a photoresist layer on the structural layer, and performing an etching process to the structural layer, wherein the photoresist layer is conductive to reduce plasma damage during the etching process.

### BRIEF DESCRIPTION OF DRAWINGS

The invention can be more fully understood by reading the subsequent detailed description and examples with references made to the accompanying drawings, wherein,

FIG. 1A to FIG. 1C show a conventional method for fabricating an integrated device.

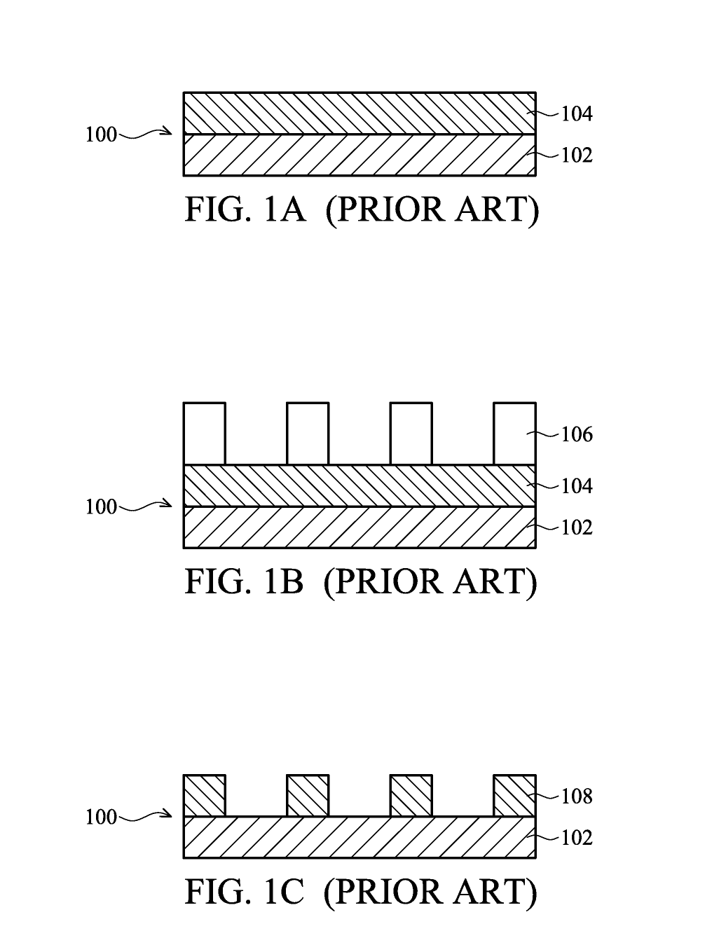

FIG. 2 shows a mechanism of plasma damage during etching.

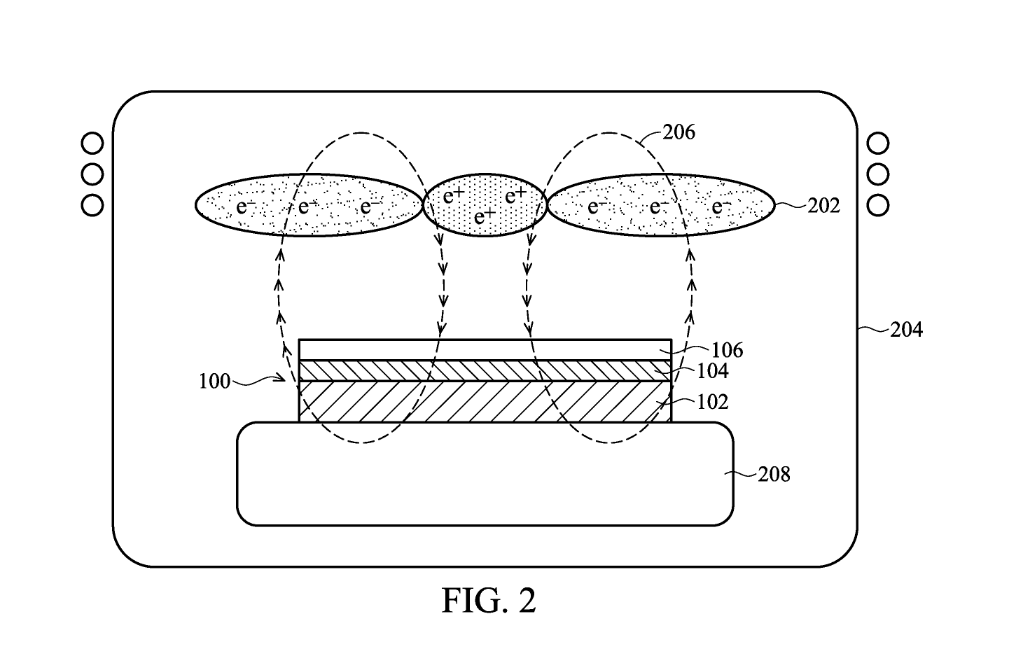

FIGS. 3A-3B shows an intermediate cross section of a method for fabricating a integrated device of an embodiment of the invention.

FIG. 4 shows a mechanism of reducing plasma damage of an embodiment of the invention.

FIG. 5 shows an intermediate cross section of a method for fabricating conductive photoresist layer of an embodiment of the invention.

### DETAILED DESCRIPTION OF INVENTION

It is understood that specific embodiments are provided as examples to teach the broader inventive concept, and one of ordinary skill in the art can easily apply the teaching of the present disclosure to other methods or apparatus. The following discussion is only used to illustrate the invention, not limit the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification do not necessarily all refer to the same embodiment. Furthermore, the particular features, structures, or characteristics may be combined in any suitable manner in one or more embodiments. It should be appreciated that the following figures are not drawn to scale; rather, these figures are merely intended for illustration.

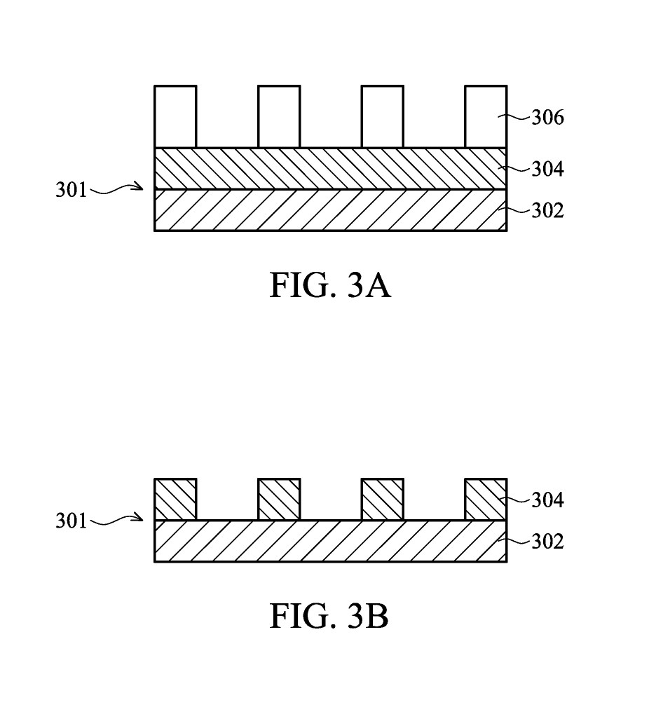

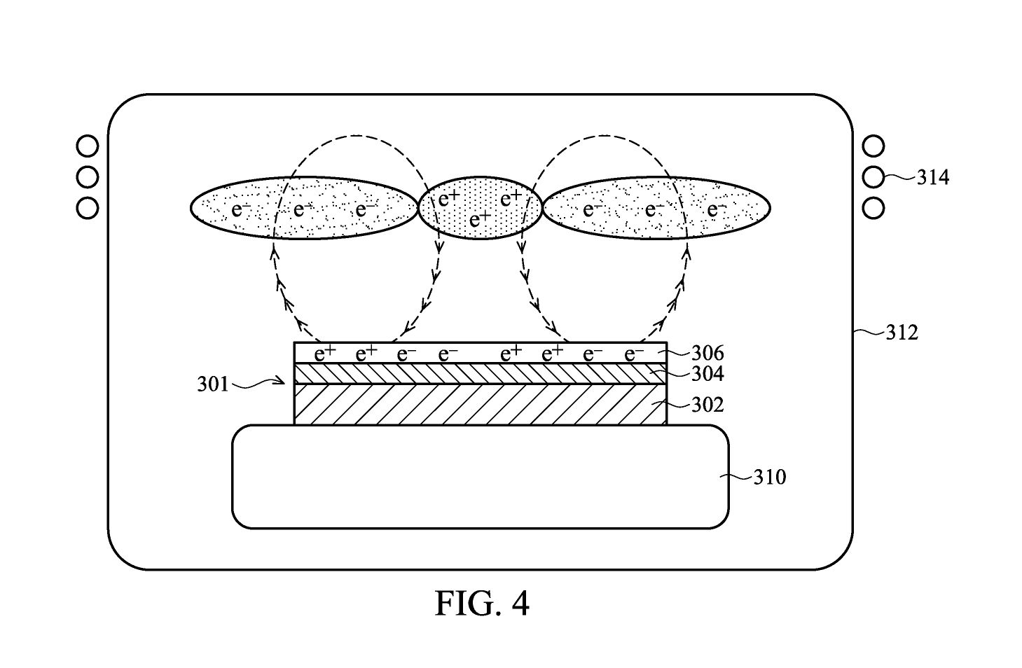

FIG. 3A illustrates schematically a wafer 301, formed by a substrate 302 of monocrystalline silicon, superimposed by a structural layer 304 to be etched. The structural layer 304 to be etched may be one of a number of materials, including silicon dioxide, silicon nitride, BPSG, epitaxy, or other layers to be etched during the manufacturing of a semiconductor chip. A photosensitive mask layer 306 is formed on top of the structural layer 304 to be etched. Referring to FIG. 3B, the device is then subjected to plasma etching, for definition of the geometry of the structural layer 304 and then the photosensitive mask layer 306 is removed. Referring to FIG. 4, during this etching, the wafer 301 is placed in an isolated chamber 312 with plasma produced by coil 314, wherein the plasma comprises electrons and positive ions. The photosensitive mask layer 306 is conductive, and it allows the electrons which have become stationary on the upper portion of the photoresist mask layer 306 to move, and recombine with the positive charges which have already reached the structural layer 304 to be etched. This prevents the formation of parasitic electric currents, which are damaging to the electronic device, and thus prevents damage from plasma. In other words, the conductive photosensitive mask layer 306 can be polarized to be a shade layer protecting the structural layer 304 and/or the substrate 302 (supported by a holder 310) thereunder from electrical field damage generated from plasma. In an example, the conductive photosensitive mask layer 306 is formed from adding conductive polymer into a photoresist, wherein the conductive polymer can be Trans-Polyacetylene, Polythiophene, Polyisothianaphthene, Polyaniline, Polypharaphenylene, Polypharaphenylene-vinylene, or Polycarbazole.

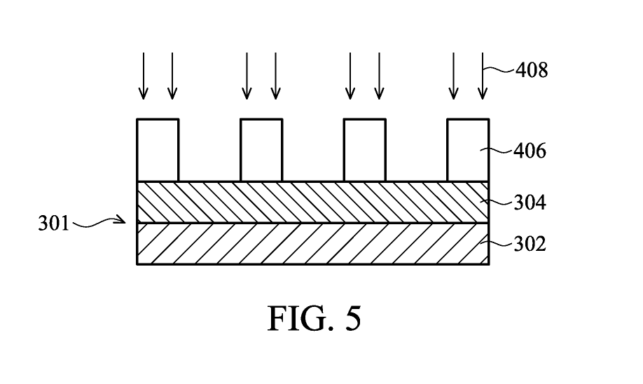

According to the embodiment, as illustrated in FIG. 5, a photosensitive masking layer 406 made of non-conductive material (for example photoresist material) is initially produced. Then, before the plasma etching step, a conductive polymer material 408 is doped into the photosensitive masking layer 406 to function as an ion trapper to reduce plasma damage during the etching process. In an example, the conductive polymer material 408 is doped in the same isolated chamber in which the plasma etching is carried out, at a pressure which is lower than atmospheric pressure, for example 10-1000 mTorr, and with a gas flow of 10-400 sccm (standard cube centimeters per minute).

It is also possible to dope the conductive polymer material 408 in a chamber different from that in which the plasma etching takes place.

The features of the process described for fabrication of electronic devices are apparent from the foregoing description. In particular, the fact is emphasized that it makes it possible to reduce, or even eliminate, damage from plasma, owing to the fact that it permits recombination of the electric charges which are separated during the etching.

In addition, it is particularly advantageous in the case when the structural layer 304 to be etched is the metallization layer used to define the electrical connections between the components of the integrated circuit. However, it can also advantageously be used in the case of isolating layers or regions of semiconductor material, whether these are produced on top of the substrate 302, or belong to the substrate 302 itself. Additional, the structural layer 304 can be a gate layer with a gate oxide layer thereunder.

The method for etching a layer with conductive photoresist layer has many advantages. First, a conductive photoresist layer can be formed by doping conductive polymers into a standard photoresist layer, which an easier process and can be integrated into a standard integrated circuit process. Second, the conductive photoresist layer has a similar chemical structure as a conventional photoresist layer, which can be removed by plasma ash. Third, the method for etching a layer with a conductive photoresist layer can reduce plasma damage during the etching process.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating an integrated device with reduced plasma damage, comprising:
providing a substrate;
forming a structural layer on the substrate;
forming a conductive photoresist layer on the structural layer, wherein the conductive photoresist layer is formed by doping a photoresist material with a conductive polymer; and
performing an etching process to the structural layer.

2. The method for fabricating an integrated device with reduced plasma damage as claimed in claim 1, wherein the conductive polymer is Trans-Polyacetylene, Polythiophene, Polyisothianaphthene, Polyaniline, Polypharaphenylene, Polypharaphenylene-vinylene, or Polycarbazole.

3. The method for fabricating an integrated device with reduced plasma damage as claimed in claim 1, wherein doping the photoresist material with conductive polymer and the etching process are performed in the same chamber.

4. The method for fabricating an integrated device with reduced plasma damage as claimed in claim 1, wherein doping the photoresist material with conductive polymer and the etching process are performed in the different chambers.

5. The method for fabricating an integrated device with reduced plasma damage as claimed in claim 1, wherein the etching process is performed under a pressure of about 10˜1000 m Torr.

6. The method for fabricating an integrated device with reduced plasma damage as claimed in claim 1, wherein the etching process is performed under a gas flow of about 10˜400 sccm.

7. The method for fabricating an integrated device with reduced plasma damage as claimed in claim 1, wherein the structural layer is a metallization layer.

8. The method for fabricating an integrated device with reduced plasma damage as claimed in claim 1, wherein the structural layer is an isolating layer.

9. The method for fabricating an integrated device with reduced plasma damage as claimed in claim 1, wherein the structural layer is a gate layer.

10. A method for fabricating an integrated device with reduced plasma damage, comprising:
providing a substrate;
forming a structural layer on the substrate;
forming a photoresist layer on the structural layer; and
performing an etching process to the structural layer, wherein the photoresist layer is conductive to reduce plasma damage during the etching process.

11. The method for fabricating an integrated device with reduced plasma damage as claimed in claim 10, wherein the conductive photoresist layer is formed by doping a photoresist material with a conductive polymer.

12. The method for fabricating an integrated device with reduced plasma damage as claimed in claim 11, wherein the conductive polymer is Trans-Polyacetylene, Polythiophene, Polyisothianaphthene, Polyaniline, Polypharaphenylene, Polypharaphenylene-vinylene, or Polycarbazole.

13. The method for fabricating an integrated device with reduced plasma damage as claimed in claim 12, wherein doping the photoresist material with conductive polymer and the etching process are performed in the different chambers.

14. The method for fabricating an integrated device with reduced plasma damage as claimed in claim 12, wherein doping the photoresist material with conductive polymer and the etching process are performed in the same chamber.

15. The method for fabricating an integrated device with reduced plasma damage as claimed in claim 10, wherein the etching process is performed under a pressure of about 10˜1000 m Torr.

16. The method for fabricating an integrated device with reduced plasma damage as claimed in claim 10, wherein the etching process is performed under a gas flow of about 10˜400 sccm.

17. The method for fabricating an integrated device with reduced plasma damage as claimed in claim 10, wherein the structural layer is a metallization layer.

18. The method for fabricating an integrated device with reduced plasma damage as claimed in claim 10, wherein the structural layer is an isolating layer.

19. The method for fabricating an integrated device with reduced plasma damage as claimed in claim 10, wherein the structural layer is a gate layer.
